(19) United States
(12) Patent Application Publication
(10) Pub. No.: US 2024/0234177 A1
(43) Pub. Date: Jul. 11, 2024

(54) WAFER PROCESSING APPARATUS

(71) Applicant: Samsung Electronics Co., Ltd., Suwon-si (KR)

(72) Inventors: Hun Yong PARK, Suwon-si (KR); Yeon Tae KIM, Suwon-si (KR); Jang Hwi LEE, Suwon-si (KR); Sang Woo BAE, Suwon-si (KR); Kyung Su KIM, Suwon-si (KR); Tae Soon PARK, Suwon-si (KR); Jung Chul LEE, Suwon-si (KR); Sung Ho JANG, Suwon-si (KR); Won Don JOO, Suwon-si (KR)

(73) Assignee: Samsung Electronics Co., Ltd., Suwon-si (KR)

(21) Appl. No.: 18/495,224

(22) Filed: Oct. 26, 2023

(30) Foreign Application Priority Data
Jan. 10, 2023 (KR) 10-2023-0003504

(51) Int. Cl. H01L 21/67; C23C 16/44; C23C 16/452; H01L 21/02

(52) U.S. Cl. CPC H01L 21/67115; C23C 16/4412; C23C 16/452; H01L 21/0228

(57) ABSTRACT

A wafer processing apparatus may include a chamber providing an internal space; and a first rib on an outer side of a first sidewall of the chamber. An outer side of the first rib may include a first portion and a second portion. A light transmittance of the first portion may be different from a light transmittance of the second portion.

### CROSS-REFERENCE TO RELATED APPLICATION

This application claims priority from Korean Patent Application No. 10-2023-0003504, filed on Jan. 10, 2023 in the Korean Intellectual Property Office and all the benefits accruing therefrom under 35 U.S.C. 119, the entire contents of which are herein incorporated by reference.

### BACKGROUND

### Technical Field

The present disclosure relates to a wafer processing apparatus.

### Description of the Related Art

Since quartz is substantially transparent to radiant energy, a process chamber for thermally processing a semiconductor wafer is generally made of quartz or a material similar to quartz.

When a pressure in a quartz chamber is much lower than an ambient pressure, a cylindrical or spherical chamber is often used in terms of strength. This is because a curved surface can best withstand an inward force. However, when a flat wafer is placed for the purpose of chemical vapor deposition in which a deposition gas flows in parallel with the wafer, a chamber wall may be parallel with an opposite flat surface of the wafer in order to obtain uniform deposition on a wafer surface. The uniform deposition may obtain a high yield of acceptable products that can be made from such a wafer. However, the flat wall can be collapsed inwardly as its internal pressure is reduced more quickly than a convex wall having a similar size and thickness.

A reinforcement plate or rib may be disposed on an outer wall of the chamber to process a force inwardly directed from a flat sidewall of the chamber. However, a deviation may occur in the amount of light transferred to the wafer due to the rib and a thickness of a film formed on the wafer may not be uniform.

### BRIEF SUMMARY

An aspect of the present disclosure is to provide a wafer processing apparatus in which a deviation of the amount of light provided to a wafer is resolved or reduced.

Aspects of the present disclosure are not limited to those mentioned above and additional aspects of the present disclosure, which are not mentioned herein, will be clearly understood by those skilled in the art from the following description of the present disclosure.

According to an embodiment of the present disclosure, a wafer processing apparatus may include a chamber providing an internal space; and a first rib on an outer side of a first sidewall of the chamber. An outer side of the first rib may include a first portion and a second portion. A light transmittance of the first portion may be different from a light transmittance of the second portion.

According to an embodiment of the present disclosure, a wafer processing apparatus may include a chamber providing an internal space; a first rib on an outer side of a first sidewall of the chamber; a first light source on the outer side of the first sidewall of the chamber; and a plate between the first light source and the first rib. The plate may include a first region and a second region. The first region of the plate may block light provided to the first rib, and the second region may transmit the light provided to the first rib.

According to an embodiment of the present disclosure, a wafer processing apparatus may include a chamber providing an internal space; a plurality of first ribs on an outer side of a first sidewall of the chamber; a plurality of first lamps on the outer side of the first sidewall of the chamber; a plurality of second ribs on an outer side of a second sidewall of the chamber; and a plurality of second lamps on the outer side of the second sidewall of the chamber. At least one outer side of the plurality of first ribs may include a first portion and a second portion, and a light transmittance of the first portion may be different from a light transmittance of the second portion.

### BRIEF DESCRIPTION OF THE DRAWINGS

The above and other aspects and features of the present disclosure will become more apparent by describing in detail example embodiments thereof with reference to the attached drawings, in which:

FIG. 1 is a view illustrating a wafer processing apparatus according to some embodiments;

FIG. 2 is a view illustrating a side of the wafer processing apparatus of FIG. 1;

FIG. 3 is a view illustrating a rib of FIG. 1;

FIG. 4 is a cross-sectional view taken along line I-I of FIG. 1;

FIG. 5 is a view illustrating a light path when there is a first rib in a chamber;

FIG. 6 is a view illustrating the amount of light on a wafer when there is a first rib in a chamber;

FIG. 7 is a view illustrating a light path when there is no first rib in a chamber;

FIG. 8 is a view illustrating a first rib according to some embodiments;

FIG. 9 is a view illustrating the amount of light on a wafer when the first rib of FIG. 8 is formed in a chamber;

FIGS. 10 to 20 are views illustrating effects of a wafer processing apparatus according to some embodiments;

FIG. 21 is a view illustrating a second rib according to some embodiments;

FIG. 22 is a view illustrating a wafer processing apparatus according to some embodiments;

FIG. 23 is a view illustrating a wafer processing apparatus according to some embodiments;

FIG. 24 is a view illustrating a wafer processing apparatus according to some embodiments;

FIG. 25 is a view illustrating a plate of FIG. 24;

FIGS. 26 and 27 are views illustrating a first region of the plate of FIG. 24; and

FIG. 28 is a view illustrating the amount of light on a wafer formed in the wafer processing apparatus of FIG. 23 or 24.

### DETAILED DESCRIPTION OF THE DISCLOSURE

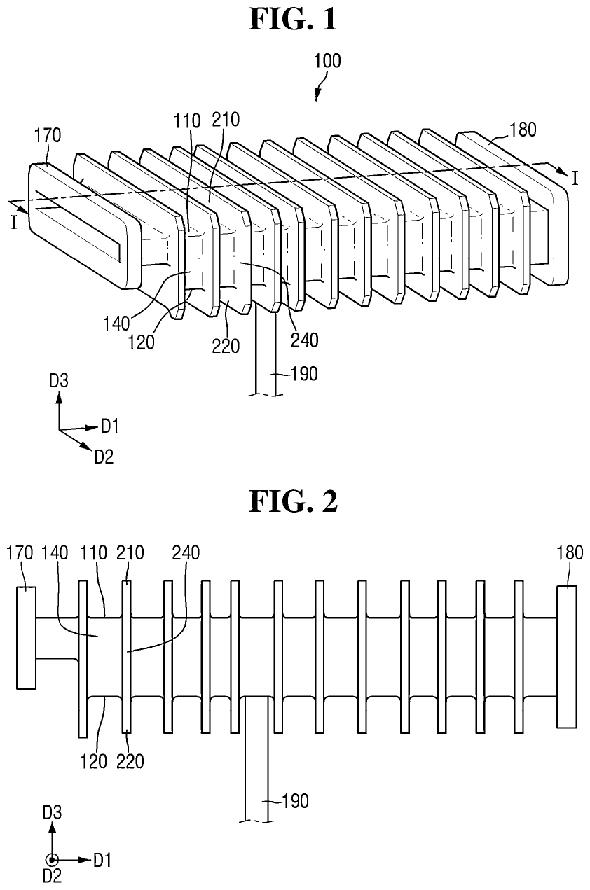

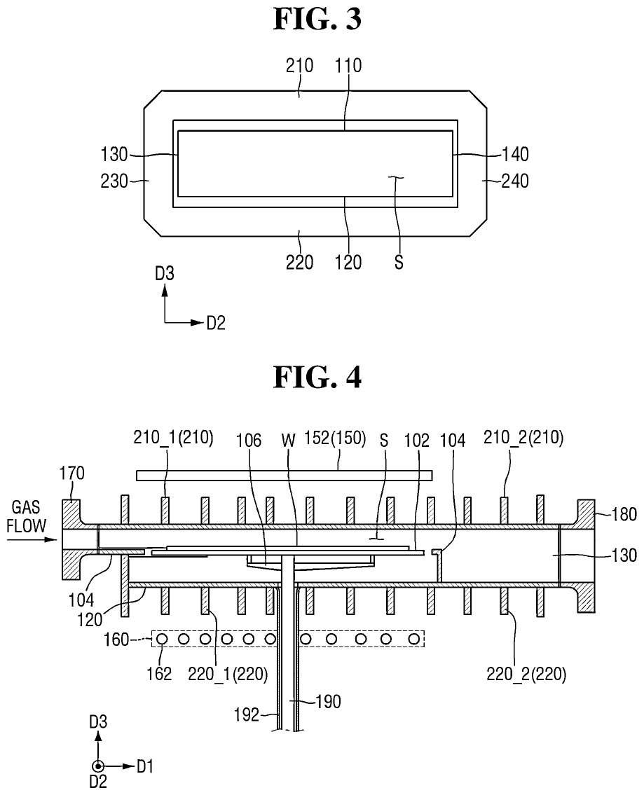

FIG. 1 is a view illustrating a wafer processing apparatus according to some embodiments. FIG. 2 is a view illustrating a side of the wafer processing apparatus of FIG. 1. FIG. 3 is a view illustrating a rib of FIG. 1. FIG. 4 is a cross-sectional view taken along line I-I of FIG. 1.

Referring to FIGS. 1 to 4, a wafer processing apparatus according to some embodiments may include a chamber 100, a susceptor 102, a plurality of first lamps 152, a plurality of second lamps 162, an inlet flange 170, an outlet flange 180 and first to fourth ribs 210, 220, 230 and 240.

The chamber 100 may provide an internal space S therein. The inner space may be provided as a space in which a substrate is processed. The chamber 100 may have a shape extended in a second direction D2. The second direction D2 may cross a first direction D1.

The chamber 100 may include first to fourth sidewalls 110, 120, 130 and 140. The first to fourth sidewalls 110, 120, 130 and 140 may be extended to be long in the second direction D2. The first sidewall 110 and the second sidewall 120 may be extended in the second direction D2, and the third sidewall 130 and the fourth sidewall 140 may be extended in a third direction D3. The third direction D3 may cross the first direction D1 and the second direction D2.

The first sidewall 110 and the second sidewall 120 may be connected to each other by the third sidewall 130 and the fourth sidewall 140. Therefore, the first to fourth sidewalls 110, 120, 130 and 140 may define an internal space S. The internal space S may be defined by inner sides of the first to fourth sidewalls 110, 120, 130 and 140.

The chamber 100 may have various shapes. The chamber 100 may be composed of (or include) quartz, for example.

The inlet flange 170 and the outlet flange 180 may be coupled to the first to fourth sidewalls 110, 120, 130 and 140. A process gas may flow into the inlet flange 170, and impurities or unreacted gas after reaction may be discharged to the outlet flange 180.

The susceptor 102 may be disposed in the internal space S of the chamber 100. The wafer W may be disposed on the susceptor 102, and the susceptor 102 may support the wafer W. A rotational shaft 190 may be coupled to a lower portion of the susceptor 102. The rotational shaft 190 may be disposed, for example, at the center of the susceptor 102. The rotational shaft 190 may be disposed in a tube 192 extended from the second sidewall 120 of the chamber 100 in the third direction D3, for example. The susceptor 102 may be supported by a support 106 connected to an upper end of the rotational shaft 190. The susceptor 102 and the wafer W may be disposed at a desired height in the chamber 100 by the rotational shaft 190. The susceptor 102 may be substantially horizontal with an upper surface of a support plate 104.

A first cover 150 and a second cover 160 may support the chamber 100, and may surround the chamber 100 so that the chamber 100 may be blocked from the outside. The first cover 150 may accommodate the plurality of first lamps 152 therein to support them. The second cover 160 may accommodate the plurality of second lamps 162 therein to support them.

The plurality of first lamps 152 may be disposed on the first sidewall 110 of the chamber 100. The plurality of first lamps 152 may be disposed to be substantially parallel with a flow of gas. The plurality of first lamps 152 may have a tube shape extended to be long in the first direction D1. The plurality of first lamps 152 may be arranged in the second direction D2.

The plurality of second lamps 162 may be disposed on the second sidewall 120 of the chamber 100. The plurality of second lamps 162 may be disposed to be perpendicular to a flow of gas. The plurality of second lamps 162 may have a tube shape extended to be long in the second direction D2. The plurality of second lamps 162 may be arranged in the first direction D1.

The first and second lamps 152 and 162 may supply radiant heat energy used in a deposition process to the inside of the chamber 100. For example, each of the first and second lamps 152 and 162 may be a halogen lamp. Although not shown, a plurality of lamp reflection plates may be disposed inside the first and second covers 150 and 160 in various forms to induce light from the first and second lamps 152 and 162 to be effectively supplied into the chamber 100.

The plurality of first ribs 210 may be disposed on the first sidewall 110. The plurality of first ribs 210 may be extended to be long in the second direction D2 along the first sidewall 110. The plurality of first ribs 210 may be arranged on the first sidewall 110 in the first direction D1, for example.

The plurality of second ribs 220 may be disposed on the second sidewall 120. The plurality of second ribs 220 may be extended to be long in the second direction D2 along the second sidewall 120. The plurality of second ribs 220 may be arranged on the second sidewall 120 in the first direction D1, for example.

The plurality of third ribs 230 may be disposed on the third sidewall 130. The plurality of third ribs 230 may be extended to be long in the third direction D3 along the third sidewall 130. The plurality of third ribs 230 may be arranged on the third sidewall 130 in the first direction D1, for example.

The plurality of fourth ribs 240 may be disposed on the fourth sidewall 140. The plurality of fourth ribs 240 may be extended to be long in the third direction D3 along the fourth sidewall 140. The plurality of fourth ribs 240 may be arranged on the fourth sidewall 140 in the first direction D1, for example. The first rib 210 and the second rib 220 may be connected by the third rib 230 and the fourth rib 240. That is, the first to fourth ribs 210, 220, 230 and 240 may completely surround an outer side of the chamber 100.

In some embodiments, the third rib 230 and the fourth rib 240 may be omitted. The first rib 210 and the second rib 220 may be disposed independently of each other. A cross-section of the first rib 210 and the second rib 220 may have various shapes such as a rectangle and a circle.

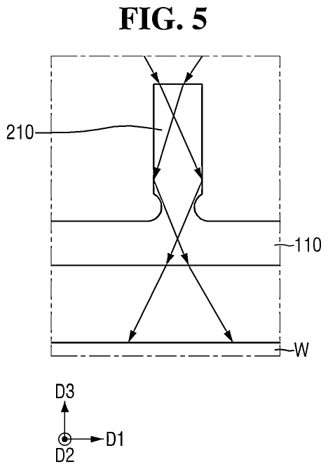

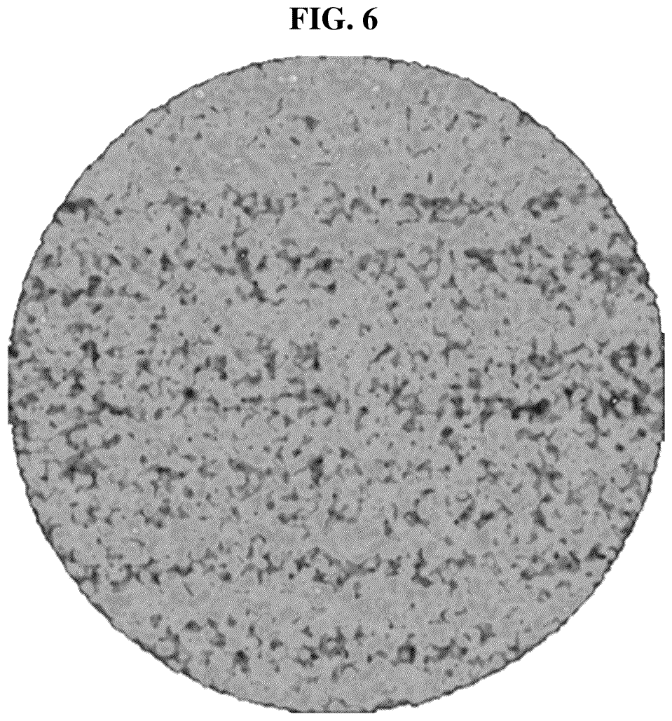

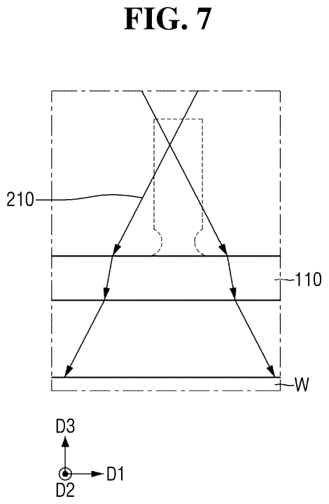

FIG. 5 is a view illustrating a light path when there is a first rib in a chamber. FIG. 6 is a view illustrating the amount of light on a wafer when there is a first rib in a chamber. FIG. 7 is a view illustrating a light path when there is no first rib in a chamber. In FIG. 6, the darker color represents the greater amount of light.

Referring to FIGS. 5 and 7, light provided from the first lamp 152 may be provided onto the wafer W by passing through the first rib 210, the first sidewall 110 and the internal space S of the chamber 100. That is, a light path deviation may occur due to refraction, reflection, etc. by the first rib 210. Therefore, when there is the first rib 210, a deviation in the amount of light may occur on the wafer W. Referring to FIG. 6, a relatively large portion of the amount of light concentrated by being guided by the first rib 210 may be generated in a line pattern shape. A deviation may occur in a thickness of a film formed on the wafer W due to the deviation in the amount of light.

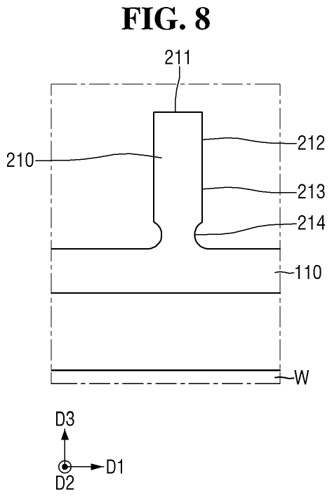

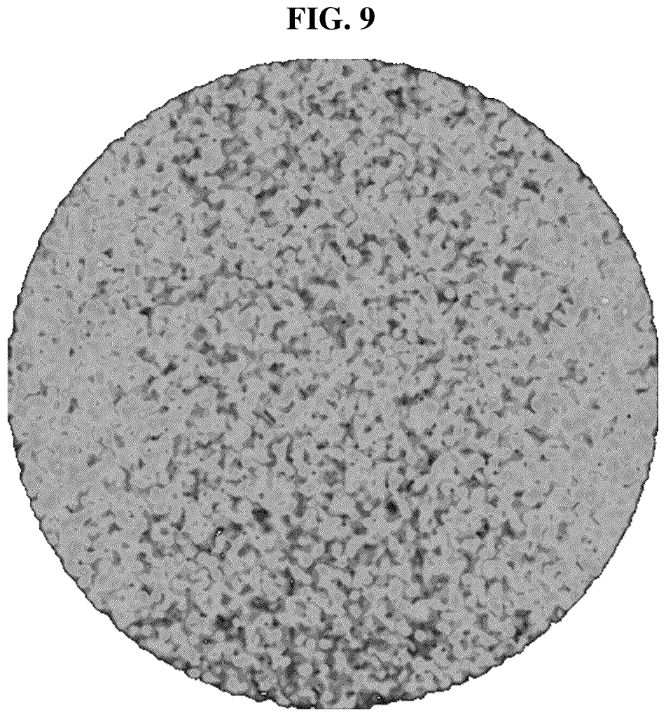

FIG. 8 is a view illustrating a first rib according to some embodiments. FIG. 9 is a view illustrating the amount of light on a wafer when the first rib of FIG. 8 is formed in a chamber. In FIG. 9, the darker color represents the greater amount of light.

Referring to FIG. 8, an outer side of the first rib 210 may include an upper surface 211 and sides 212, 213 and 214. The upper surface 211 may be based on the third direction D3. The first side 212 may be a side connected to the upper surface 211, the third side 214 may be a side connected to the first sidewall 110, and the second side 213 may be a side connected to the first side 212 and the third side 214. The third side 214 may be concave. The first side 212 may correspond to a first portion of a sidewall of the first rib 210 for an upper region of the first rib 210. The second side 213 may correspond to a second portion of the sidewall of the first rib 210 for an intermediate region of the first rib 210. The third side 214 may correspond to a third portion of the sidewall of the first rib 210 for a lower region of the first rib 210. The intermediate region of the first rib 210 may be between the upper region of the first rib 210 and the lower region of the first rib 210 in the third direction D3.

The outer side of the first rib 210 according to some embodiments may include a first portion and a second portion, which are different from each other in light transmittance. In some embodiments, the first portion may be at least a portion of the outer side of the first rib 210, and the second portion may be the other portion except the first portion of the outer side of the first rib 210.

The light transmittance of the first portion may be smaller than that of the second portion. The first portion may be referred to as a diffuser surface. For example, the light transmittance of the first portion may be smaller than that of the second portion but may not be zero. For another example, the light transmittance of the first portion may be 0, and the first portion may be an opaque surface through which light is not transmitted.

For example, the first portion may be the upper surface 211 and the first side 212 of the first rib 210, and the second portion may be the second side 213 and the third side 214 of the first rib 210. Therefore, the amount of light provided onto the wafer W by transmitting the upper surface 211 and the first side 212 of the first rib 210 may be reduced. Referring to FIGS. 6 and 9, when the diffuser surface is formed in the first rib 210, a portion (e.g., the line pattern shape portion in FIG. 6) on which light is relatively concentrated may be reduced. Therefore, the deviation in the thickness of the film formed on the wafer W due to the deviation in the amount of light may be resolved or reduced.

In some other embodiments, the entire outer side of the first rib 210 may be a diffuser surface. The upper surface 211 and the first to third sides 212, 213 and 214 of the first rib 210 may be diffuser surfaces.

The diffuser surface according to some embodiments may be formed by various surface processing methods such as a sand blasting method, a chemical etching method, a method using a laser and the like. For example, the diffuser surface may be formed by sand blasting at least a portion of the outer side of the first rib 210. Therefore, a surface roughness of the first portion may be greater than that of the second portion. For example, the first portion may have a surface roughness of Ra 0.5 μm to 5 μm, for example.

The diffuser surface according to some other embodiments may be a surface where a thin film, a hologram, a grating pattern, an opaque layer or the like is formed on at least a portion of the outer side of the first rib 210.

Referring back to FIG. 4, the first rib 210 may include a (1-1)th rib 210_1 overlapped with the plurality of first lamps 152 (for example, overlapped in the third direction D3) and a (1-2)th rib 210_2 that is not overlapped with the plurality of first lamps 152.

In some embodiments, the (1-1)th rib 210_1 and the (1-2)th rib 210_2 may include a diffuser surface.

In some other embodiments, the (1-1)th rib 210_1 includes a diffuser surface, but the (1-2)th rib 210_2 may not include a diffuser surface. The diffuser surface is formed on at least a portion of an outer side of the (1-1)th rib 210_1 but is not formed on an outer side of the (1-2)th rib 210_2, and the outer side of the (1-2)th rib 210_2 may have a uniform light transmittance.

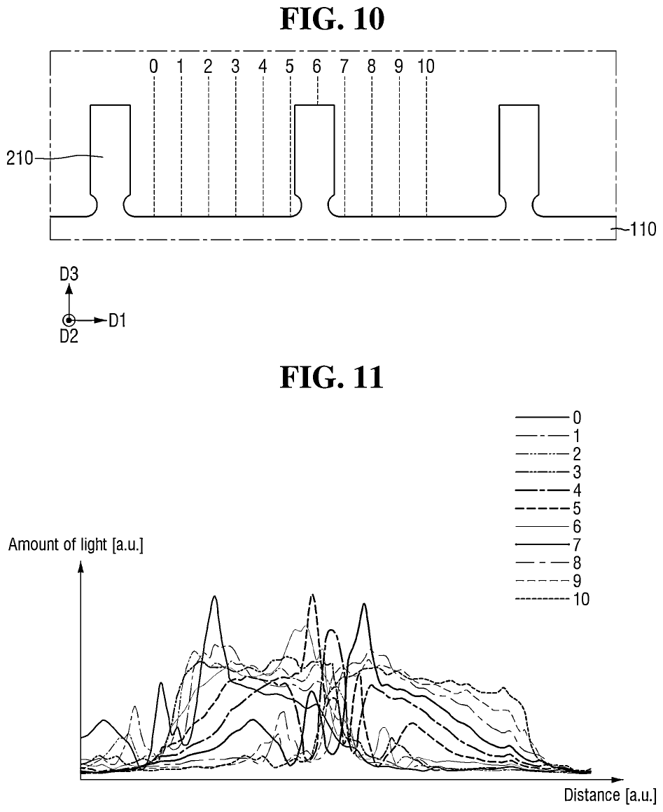

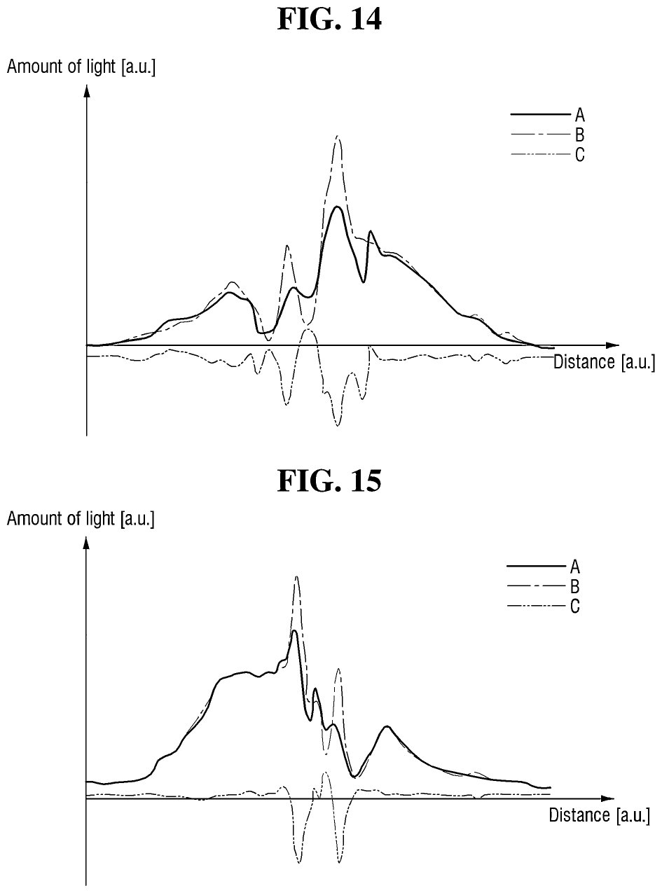

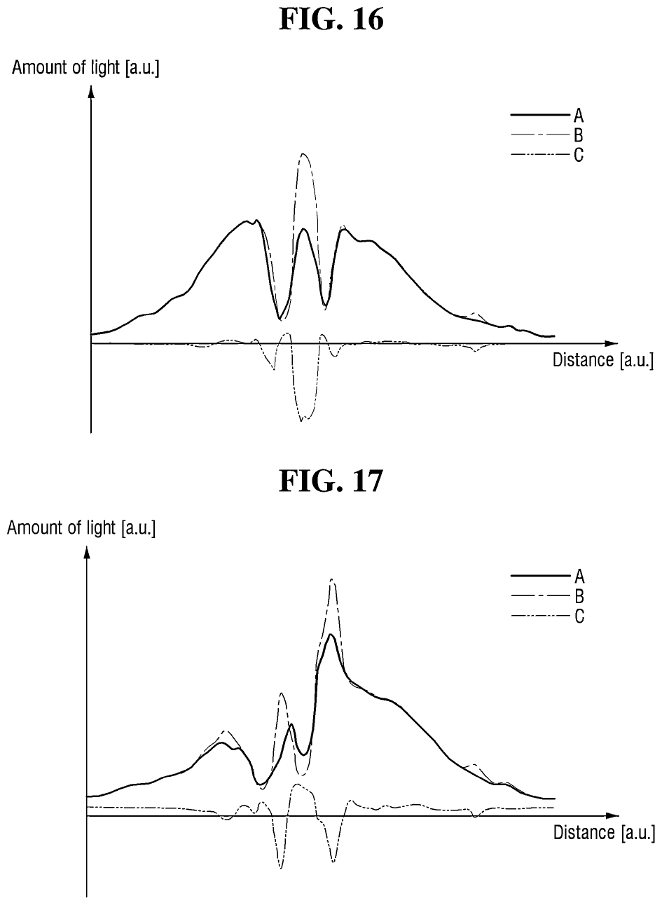

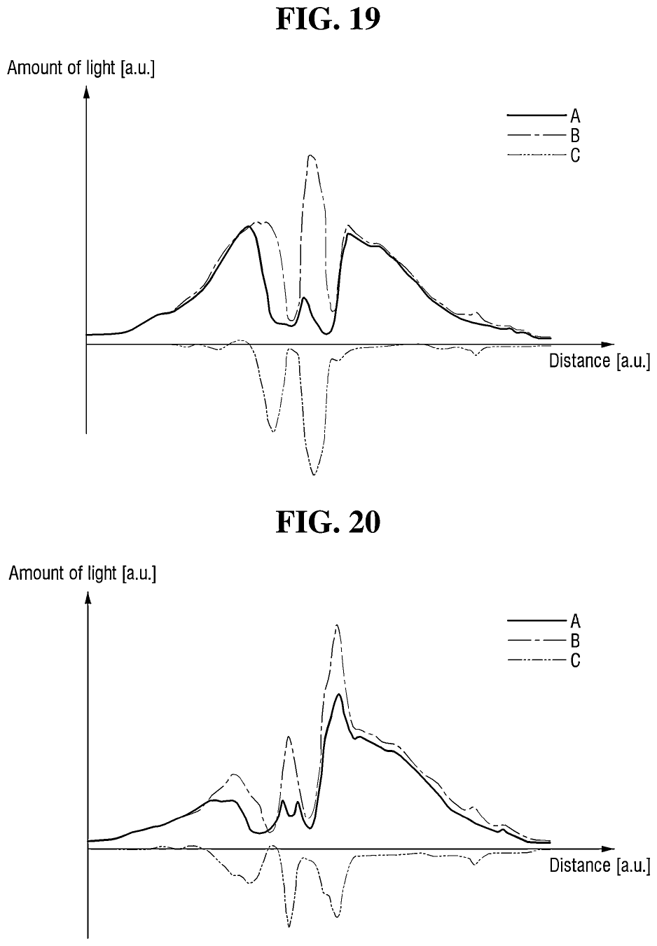

FIGS. 10 to 20 are views illustrating effects of a wafer processing apparatus according to some embodiments.

FIG. 11 is a graph illustrating the amount of light according to a distance from a position of 0 in FIG. 10 when one first lamp (152 in FIG. 4) is disposed at each of positions from 0 to 10 in FIG. 10. Referring to FIGS. 10 and 11, when the first lamp 152 is positioned at positions of 0, 5, 6 and 7, a deviation in the amount of light is relatively large.

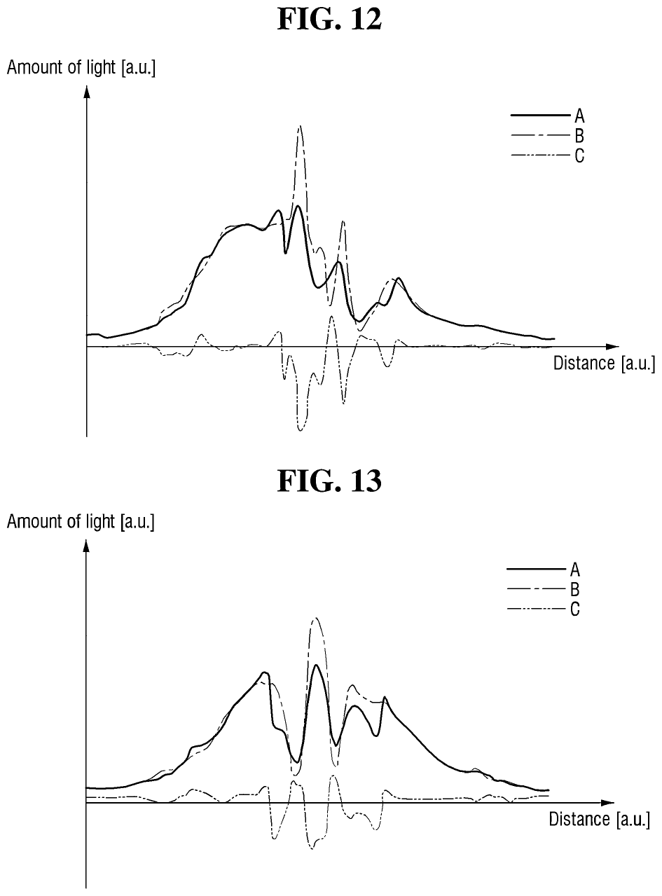

FIGS. 12 to 14 are graphs illustrating the amount of light according to a distance from a position of 0 in FIG. 10 when the first lamp 152 is at each of positions of 5, 6 and 7 in FIG. 10. In FIGS. 12 to 14, ‘A’ represents an experimental result when the upper surface 211 and the third side 214 of the first rib 210 are diffuser surfaces, ‘B’ represents an experimental result when there is no diffuser surface in the first rib 210, and ‘C’ represents a difference between ‘A’ and ‘B.’

FIGS. 15 to 17 are graphs illustrating the amount of light according to a distance from a position of 0 in FIG. 10 when the first lamp 152 is at each of positions of 5, 6 and 7 in FIG. 10. In FIGS. 15 to 17, ‘A’ represents an experimental result when the upper surface 211 and the first side 212 of the first rib 210 are diffuser surfaces, ‘B’ represents an experimental result when there is no diffuser surface in the first rib 210, and ‘C’ represents a difference between ‘A’ and ‘B.’

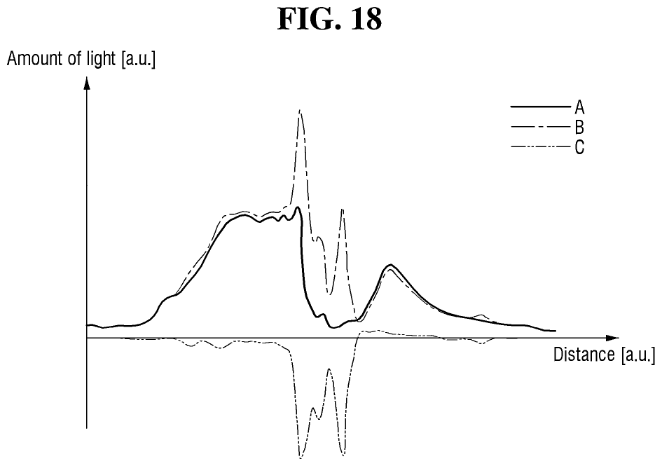

FIGS. 18 to 20 are graphs illustrating the amount of light according to a distance from a position of 0 in FIG. 10 when the first lamp 152 is at each of positions of 5, 6 and 7 in FIG. 10. In FIGS. 18 to 17, ‘A’ represents an experimental result when the upper surface 211 of the first rib 210 is a diffuser surface, ‘B’ represents an experimental result when there is no diffuser surface in the first rib 210, and ‘C’ represents a difference between ‘A’ and ‘B.’ At this time, the upper surface 211 of the first rib 210 may be an opaque surface. That is, light may not be transmitted to the upper surface 211 of the first rib 210.

Referring to FIGS. 12 to 20, when a diffuser surface is formed on at least a portion of the outer side of the first rib 210, a deviation in the amount of light provided onto the wafer W may be reduced. Therefore, the deviation in the thickness of the film formed on the wafer W due to the deviation in the amount of light may be resolved or reduced.

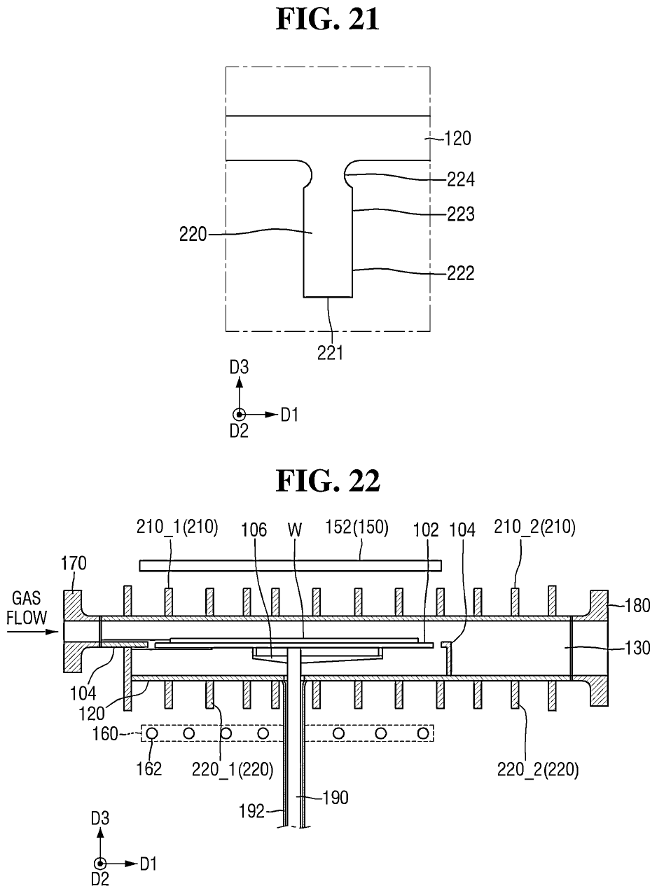

FIG. 21 is a view illustrating a second rib according to some embodiments.

Referring to FIGS. 4 and 21, the outer side of the second rib 220 may include a lower surface 221 and sides 222, 223 and 224. The lower surface 221 may be based on the third direction D3. The fourth side 222 may be a side connected to the lower surface 221, the sixth side 224 may be a side connected to the second sidewall 120, and the fifth side 223 may be a side connected to the fourth side 222 and the sixth side 224.

In some embodiments, the outer side of the second rib 220 may not include a diffuser surface. That is, the outer side of the second rib 220 may have a uniform light transmittance.

In some other embodiments, at least a portion of the outer side of the second rib 220 may include a diffuser surface. The outer side of the second rib 220 may include a diffuser surface independently of the outer side of the first rib 210.

Meanwhile, the second rib 220 may include a (2-1)th rib 220_1 overlapped with the plurality of second lamps 162 (for example, overlapped in the third direction D3) and a (2-2)th rib 220_2 that is not overlapped with the plurality of second lamps 162.

In some embodiments, the (2-1)th rib 220_1 and the (2-2)th rib 220_2 may include a diffuser surface.

In some other embodiments, the (2-1)th rib 220_1 may include a diffuser surface, but the (2-2)th rib 220_2 may not include a diffuser surface. The diffuser surface is formed on at least a portion of the outer side of the (2-1)th rib 220_1, but the diffuser surface is not formed on the outer side of the (2-2)th rib 220_2, and the outer side of the (2-2)th rib 220_2 may have a uniform light transmittance.

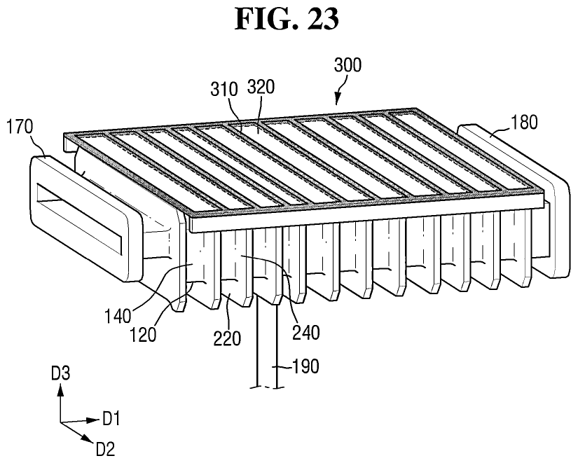

FIG. 22 is a view illustrating a wafer processing apparatus according to some embodiments. For convenience of description, the following description will be based on differences from those described with reference to FIGS. 1 to 21.

Referring to FIG. 22, in some embodiments, the plurality of second lamps 162 may not overlap the second rib 220 in the third direction D3. That is, the plurality of second lamps 162 may be disposed between the second ribs 220 adjacent to each other. Referring to FIGS. 10 and 11, the deviation in the amount of light may be large in a region adjacent to the first rib 210. That is, the deviation in the amount of light may be adjusted by adjusting the arrangement of the second lamp 162 and the second rib 220. Since the second lamp 162 and the second rib 220 do not overlap each other in the third direction D3, the deviation in the amount of light due to the arrangement of the second lamp 162 and the second rib 220 may be reduced.

FIG. 23 is a view illustrating a wafer processing apparatus according to some embodiments. For convenience of description, the following description will be based on differences from those described with reference to FIGS. 1 to 21.

Referring to FIG. 23, the wafer processing apparatus according to some embodiments may further include a plate 300. The plate 300 may be disposed between the chamber 100 and the plurality of first lamps 152. The plate 300 may be disposed on the first sidewall 110 of the chamber 100. The plate 300 may be disposed on the first rib 210.

The first to fourth ribs 210, 220, 230, 240 may not include a diffuser surface.

The plate 300 may include a first region 310 and a second region 320. The first region 310 and the second region 320 may be alternately disposed. The first region 310 may overlap the first rib 210, and the second region 320 may not overlap the first rib 210. The first region 310 may be opaque, and the second region 320 may be transparent. Light provided to the chamber 100 may be blocked in the first region 310 and transmitted in the second region 320. Therefore, the deviation in the amount of light on the wafer due to the first rib 210 may be resolved or reduced by the plate 300 without a diffuser surface.

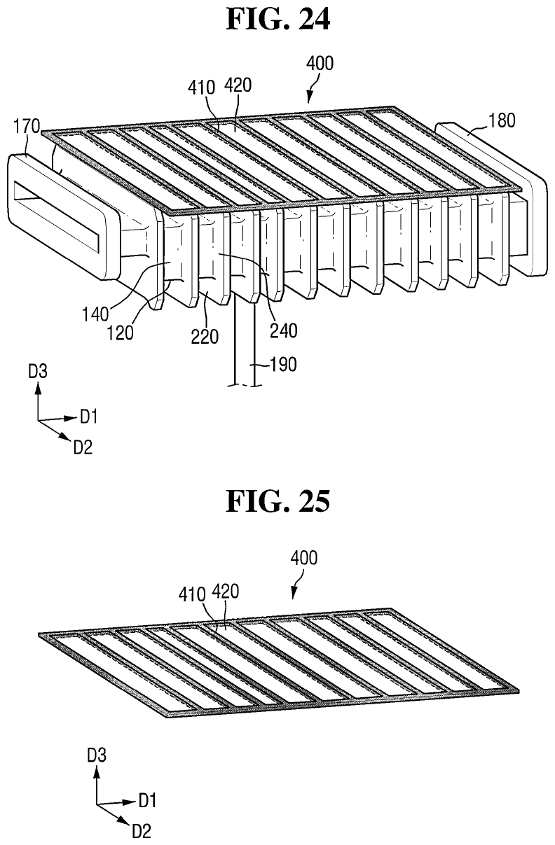

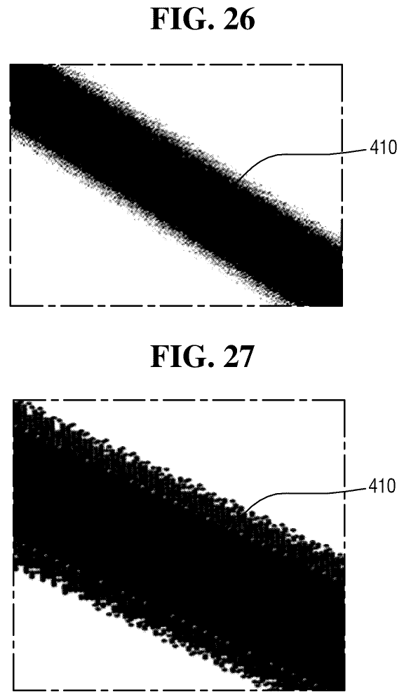

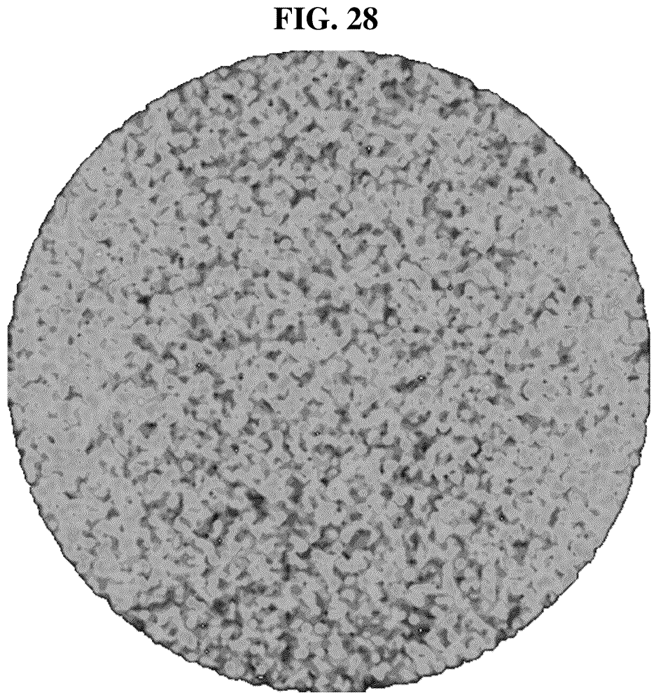

FIG. 24 is a view illustrating a wafer processing apparatus according to some embodiments. FIG. 25 is a view illustrating a plate of FIG. 24. FIGS. 26 and 27 are views illustrating a first region of the plate of FIG. 24, and FIG. 28 is a view illustrating the amount of light on a wafer formed in the wafer processing apparatus of FIG. 23 or 24. In FIG. 28, the darker color represents the greater amount of light. For convenience of description, the following description will be based on differences from those described with reference to FIGS. 1 to 21.

Referring to FIGS. 24 and 25, the wafer processing apparatus according to some embodiments may further include a plate 400. The plate 400 may be disposed between the chamber 100 and the plurality of first lamps 152. The plate 400 may be disposed on the first sidewall 110 of the chamber 100. The plate 400 may be disposed on the first rib 210.

The first to fourth ribs 210, 220, 230 and 240 may not include a diffuser surface.

The plate 400 may be composed of (or include), for example, quartz.

The plate 400 may include a first region 410 and a second region 420. The first region 410 and the second region 420 may be alternately disposed. The first region 410 may overlap the first rib 210, and the second region 420 may not overlap the first rib 210.

The first region 410 may include a pattern. Referring to FIG. 26, the first region 410 may include a gradation pattern. Referring to FIG. 27, the first region 410 may include a digit pattern.

Light provided to the chamber 100 may be blocked in the first region 410 and transmitted in the second region 420. Therefore, the deviation in the amount of light provided onto the wafer W due to the first rib 210 may be resolved or reduced by the plate 400 without a diffuser surface.

Referring to FIGS. 6 and 28, when the plate 300 is disposed on the chamber 100 as shown in FIG. 23 or when the plate 400 is disposed on the chamber 100 as shown in FIG. 24, a portion (e.g., the line pattern shape portion in FIG. 6) on which the light is relatively concentrated may be reduced. Therefore, the deviation in the thickness of the film formed on the wafer W due to the deviation in the amount of light may be resolved or reduced.

Although the embodiments of the present disclosure have been described with reference to the accompanying drawings, it will be apparent to those skilled in the art that the present disclosure can be manufactured in various forms without being limited to the above-described embodiments and can be embodied in other specific forms without departing from technical spirits and characteristics of embodiments of inventive concepts. Thus, the above embodiments are to be considered in all respects as illustrative and not restrictive.

What is claimed is:

1. A wafer processing apparatus comprising:
a chamber providing an internal space; and
a first rib on an outer side of a first sidewall of the chamber, wherein
an outer side of the first rib includes a first portion and a second portion, and
a light transmittance of the first portion is different from a light transmittance of the second portion.

2. The wafer processing apparatus of claim 1, wherein a surface roughness of the first portion is different from a surface roughness of the second portion.

3. The wafer processing apparatus of claim 1, wherein
the first portion is an upper surface of the first rib, and
the second portion is at least a portion of a side of the first rib.

4. The wafer processing apparatus of claim 3, wherein light transmittance of the first portion is smaller than that of the second portion.

5. The wafer processing apparatus of claim 1, wherein
the first portion is an upper surface of the first rib and an upper region of the outer side of the first rib,
the upper region of the outer side of the first rib is connected to the upper surface of the first rib,
the second portion is a lower region of the outer side of the first rib, and
the lower region of the outer side of the first rib is connected to the first sidewall of the chamber.

6. The wafer processing apparatus of claim 5, wherein light transmittance of the first portion is smaller than that of the second portion.

7. The wafer processing apparatus of claim 5, wherein at least a portion of the second portion is concave.

8. The wafer processing apparatus of claim 1, further comprising:
a second rib spaced apart from the first rib on the outer side of the first sidewall of the chamber, wherein
an outer side of the second rib includes a third portion and a fourth portion, and
a light transmittance of the third portion is different from a light transmittance of the fourth portion.

9. The wafer processing apparatus of claim 1, further comprising:
a second rib spaced apart from the first rib on the outer side of the first sidewall of the chamber, wherein
an outer side of the second rib includes a third portion and a fourth portion, and
a light transmittance of the third portion is equal to a light transmittance of the fourth portion.

10. The wafer processing apparatus of claim 9, further comprising:
a lamp on the outer side of the first sidewall of the chamber, wherein
the first rib overlaps the lamp, and
the second rib does not overlap the lamp.

11. The wafer processing apparatus of claim 1, further comprising:
a second rib on an outer side of a second sidewall of the chamber.

12. The wafer processing apparatus of claim 11, wherein
the outer side of the second rib includes a third portion and a fourth portion, and
a light transmittance of the third portion is different from a light transmittance of the fourth portion.

13. The wafer processing apparatus of claim 12, wherein a surface roughness of the third portion is different from a surface roughness of the fourth portion.

14. The wafer processing apparatus of claim 11, further comprising:
a lamp on the outer side of the second sidewall, wherein
the lamp does not overlap the second rib.

15. A wafer processing apparatus comprising:
a chamber providing an internal space;
a first rib on an outer side of a first sidewall of the chamber;
a first light source on the outer side of the first sidewall of the chamber; and
a plate between the first light source and the first rib, wherein
the plate includes a first region and a second region,
the first region of the plate blocks light provided to the first rib, and
the second region transmits the light provided to the first rib.

16. The wafer processing apparatus of claim 15, wherein the first region is on the upper surface of the first rib.

17. The wafer processing apparatus of claim 15, wherein the first region include pattern.

18. The wafer processing apparatus of claim 15, wherein the plate includes quartz.

19. A wafer processing apparatus comprising:
a chamber providing an internal space;
a plurality of first ribs on an outer side of a first sidewall of the chamber;
a plurality of first lamps on the outer side of the first sidewall of the chamber;
a plurality of second ribs on an outer side of a second sidewall of the chamber; and
a plurality of second lamps on the outer side of the second sidewall of the chamber, wherein
at least one outer side of the plurality of first ribs includes a first portion and a second portion, and
a light transmittance of the first portion is different from a light transmittance of the second portion.

20. The wafer processing apparatus of claim 19, wherein a surface roughness of the first portion is different from a surface roughness of the second portion.
